(19) United States
(12) Patent Application Publication
(10) Pub. No.: US 2006/0154492 A1
(43) Pub. Date: Jul. 13, 2006

(54) Forming method of low dielectric constant insulating film of semiconductor device, semiconductor device, and low dielectric constant insulating film forming apparatus

(75) Inventors: Shinji Ide, Amagasaki-shi (JP); Masaru Sasaki, Amagasaki-shi (JP); Satohiko Hoshino, Nirasaki-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 11/322,318

(22) Filed: Jan. 3, 2006

Related U.S. Application Data
(63) Continuation-in-part of application No. PCT/JP04/09330, filed on Jul. 1, 2004.

(30) Foreign Application Priority Data
Jul. 2, 2003 (JP) 2003-190501

(51) Int. Cl. H01L 21/31; H01L 21/469

(52) U.S. Cl. 438/781

(57) ABSTRACT

It is an object of the present invention to cure an insulating film of a semiconductor device in a short time while keeping a low dielectric constant. In the present invention, a coating film made of porous MSQ is formed on a substrate, the substrate on which the porous MSQ is formed is placed in a vacuum vessel, and high-density plasma processing at a low electron temperature based on microwave excitation is applied to the coating film by using a plasma substrate processing apparatus, thereby causing an intermolecular dehydration-condensation reaction of hydroxyls in a molecule and another molecule included in the porous MSQ to bond the molecules together, so that a cured insulating film is generated while a low dielectric constant is maintained.

This is a continuation in part of PCT Application No. PCT/JP2004/009330, filed on Jul. 1, 2004, which claims the benefit of Japanese Patent Application No. 2003-190501, filed on Jul. 2, 2003, all of which are incorporated herein by reference.

### BACKGROUND OF THE INVENTION

The present invention relates to a forming method of a low dielectric constant insulating film of a semiconductor device, a semiconductor device, and a low dielectric constant insulating film forming apparatus, and more particularly, to a method and an apparatus which generate plasma by using a microwave, thereby curing a low dielectric constant coating film used as an interlayer insulation film of a semiconductor device while maintaining a low dielectric constant.

### DESCRIPTION OF THE RELATED ART

In accordance with an increase in integration degree of a semiconductor integrated circuit, an increase in wiring delay time ascribable to an increase in inter-wiring capacitance, which is a parasitic capacitance between metal wirings, comes to be a hindrance to achieving a higher performance of the semiconductor integrated circuit. The wiring delay time is proportional to a product of a resistance of the metal wiring and the wiring capacitance. In order to lower the resistance of the metal wiring for achieving a shorter wiring delay time, highly conductive copper (Cu) is used instead of conventionally used aluminum (Al).

Further, a possible way of reducing the wiring capacitance is to lower a dielectric constant (k) of an interlayer insulating film formed between the metal wirings. As a low dielectric constant interlayer insulating film, used is an insulating film which is lower in dielectric constant than conventional oxide silicon (SiO₂). Such a low dielectric constant insulating film is formed on a wafer by, for example, a SOD (Spin-on-Dielectric) system. Specifically, the SOD system coats the wafer with a high-molecular forming material in liquid form and applies curing such as heating thereto, thereby forming an insulating film. The dielectric constant of the coating film, at the stage where it is formed by the SOD system, keeps a low value.

However, the insulating film, if left as it is after being formed, is low in mechanical strength and low in adhesiveness to a base substrate. Therefore, the insulating film is thermally cured while keeping its low dielectric constant. The insulating film increases in strength by a chemical bonding force when molecules thereof are bonded into a polymer by this thermal curing, so that the peeling of the films at the time of chemical mechanical polishing (CMP) is prevented.

Conventionally, for curing the insulating film, for example, 30 to 60 minute heating is applied by using a furnace. However, this method not only requires a long time for the processing but also cannot attain predetermined mechanical hardness, and the long heating may possibly increase the dielectric constant.

Another curing method is to use an electron beam, but this method, though only taking 2 to 6 minutes for curing, can only achieve insufficient hardness. Therefore, a method of curing the insulating film in a short time while further lowering the dielectric constant is being demanded.

Further, Japanese Patent Application Laid-open No. Hei 8-236520 describes a method of curing an insulating film by generating plasma in a parallel-plate plasma reactor.

A first object of the method of curing the insulating film by generating the plasma in the parallel-plate plasma reactor described in the above Japanese Patent Application Laid-open No. Hei 8-236520 is to cure a SOG film without producing any residues or the like. A second object of this method is to prevent property deterioration of current/voltage due to moisture generation when a photosensitive film is removed after a subsequent masking process.

The above-described method reduces a defect in the SOG film such as —OH and —CH₃ causing leakage current by curing the insulating film at a temperature of 200° C. to 450° C. for 60 minutes. However, in order to maintain the low dielectric constant, CH₃ is indispensable, and exposing the SOG film to the plasma atmosphere for no less than 60 minutes has a problem that CH₃ disappears to make the dielectric constant higher.

### SUMMARY OF THE INVENTION

It is a major object of the present invention to provide a forming method of an insulating film of a semiconductor device capable of curing the insulating film of the semiconductor device in a short time while maintaining a low dielectric constant, and to provide a semiconductor device having an insulating film formed by, for example, this method, and a low dielectric constant insulating film forming apparatus.

A forming method of a low dielectric constant insulating film of a semiconductor device of the present invention includes the step of placing in a vacuum vessel a substrate on which a coating film is formed and applying, to the coating film, high-density plasma processing at a low electron temperature, thereby curing the coating film while keeping a low dielectric constant.

Accordingly, it is possible to cure the coating film in a short time while keeping the low dielectric constant.

Preferably, the curing step includes curing the coating film in a processing time of five minutes or less. This can increase the number of the substrates processable per hour, resulting in an improved throughput in semiconductor processing steps.

Preferably, the curing step includes generating plasma with a low electron temperature of 0.5 eV to 1.5 eV and an electron density of 10¹¹ to 10¹³ electrons/cm³. Thus curing the coating film at the low electron temperature makes it possible to reduce energy of an electron absorbed in the coating film, so that a damage given to the coating film when the electron collides with the coating film can be alleviated.

Preferably, the curing step includes causing an intermolecular dehydration-condensation reaction by hydroxyls in a molecule and another molecule included in the coating film.

According to another aspect, a semiconductor device of another invention of the present invention includes: a substrate; and a low dielectric constant insulating film applied on the substrate and cured by high-density plasma processing at a low electron temperature.

An example of a molecular structure of the insulating film cured by the high-density plasma processing is one including a Si—O—Si bond.

According to still another aspect, a low dielectric constant insulating film forming apparatus of the present invention includes: a curing means for curing a coating film while keeping a low dielectric constant, by placing in a vacuum vessel a substrate on which a coating film is formed and applying, to the coating film, high-density plasma processing at a low electron temperature based on microwave excitation.

An example of the curing means is one generating plasma with a low electron temperature of 0.5 eV to 1.5 eV and an electron density of 10¹¹ to 13¹³ electrons/cm³.

According to this invention, the substrate on which the low dielectric constant coating film is formed is placed in the vacuum vessel and the high-density plasma processing is applied to the coating film at the low electron temperature based on the microwave excitation, whereby it is possible to cure the coating film in a short time while keeping the low dielectric constant and in addition, to bring the coating film in close contact with the base substrate.

Further, setting a processing time of the curing to five minutes or less makes it possible to increase the number of the substrates processable per hour, so that the throughput in the semiconductor processing processes can be improved.

In addition, generating the plasma with the low electron temperature of 0.5 eV to 1.5 eV and the electron density of 10¹¹ to 13¹³ electrons/cm³ makes it possible to reduce electron energy absorbed by the coating film, so that the damage given thereto when the electron collides with the coating film can be alleviated.

### BRIEF DESCRIPTION OF THE DRAWINGS

FIG. 1 is a cross-sectional view showing a plasma substrate processing apparatus used for forming a low dielectric constant insulating film of the present invention;

FIG. 2 is a perspective view partly in section of a slot plate shown in FIG. 1;

FIG. 3A to FIG. 3C are cross-sectional views of an insulating film, showing processes for forming the low dielectric constant insulation film according to one embodiment of the present invention, FIG. 3A showing a substrate before being processed, FIG. 3B showing a state in which a coating film is formed on the substrate, and FIG. 3C showing a state in which the insulating film is formed by curing the coating film;

FIG. 4A is a view showing a molecular structure of the insulating film before being cured and FIG. 4B is a view showing a molecular structure of the insulating film cured by the plasma substrate processing apparatus;

FIG. 5 is a chart showing the correlation between curing time and dielectric constant in curing in the embodiment of the present invention and in conventional curing using an electron beam;

FIG. 6 is a chart showing the correlation between curing time and modulus of elasticity in the curing in the embodiment of the present invention and in the conventional curing using the electron beam;

FIG. 7A is a table showing, for comparison, concrete experiment results of curing in another embodiment of the present invention and in conventional curing using a furnace, FIG. 7B is a table showing, for comparison, concrete experiment results of the curing in the other embodiment of the present invention and the curing using the electron beam, and FIG. 7C is a table showing, for comparison, concrete experiment results of the curing in the other embodiment of the present invention and the curing using the electron beam;

FIG. 8 is a chart showing changes in dielectric constant and modulus of elasticity when a mixture ratio of hydrogen gas is varied in the embodiment of the present invention;

FIG. 9 is a chart showing a change in methyl residual ratio when the mixture ratio of the hydrogen gas is varied in the embodiment of the present invention;

FIG. 10 is a chart showing changes in dielectric constant and modulus of elasticity when process pressure is varied in the embodiment of the present invention; and

FIG. 11 is a chart showing a change in methyl residual ratio when the process pressure is varied in the embodiment of the present invention.

### DETAILED DESCRIPTION OF THE INVENTION

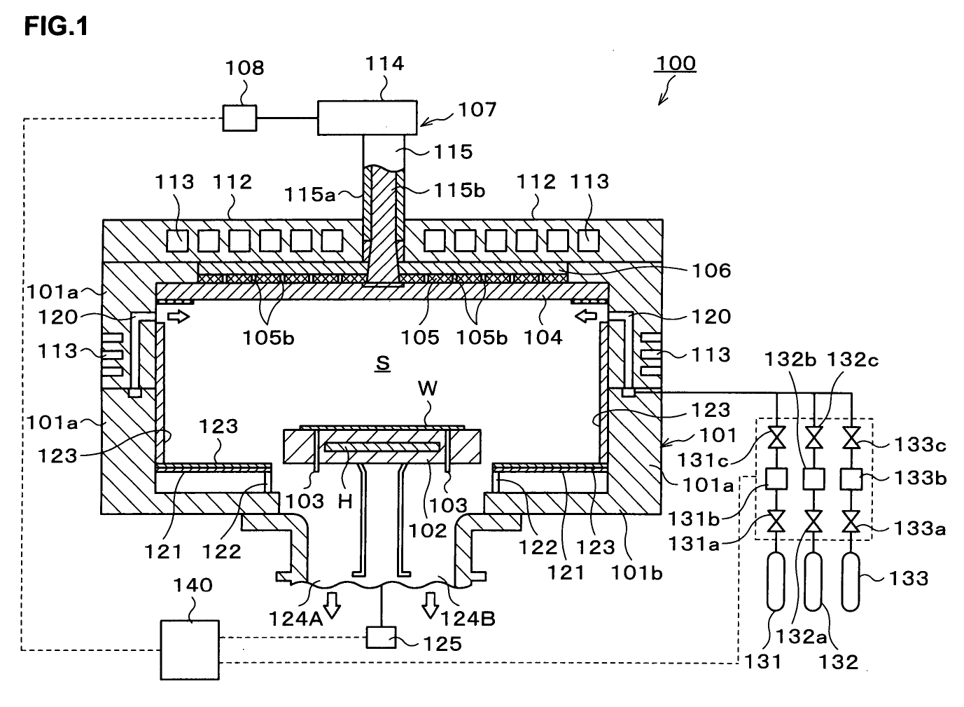

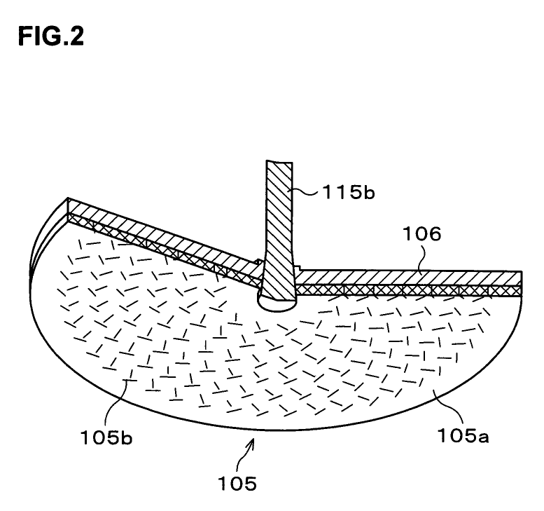

Hereinafter, embodiments of the present invention will be described with reference to the drawings. FIG. 1 is a cross-sectional view of a plasma substrate processing apparatus used for forming an insulating film of the present invention. FIG. 2 is a perspective view partly in section of a slot plate shown in FIG. 1.

As shown in FIG. 1, the plasma substrate processing apparatus 100 has a plasma processing chamber 101 in a cylindrical shape as a whole, with a sidewall 101a and a bottom portion 101b thereof, for example, being made of conductors such as aluminum, and an inner part of the plasma processing chamber 101 is formed as an airtight processing space S. The plasma processing chamber 101 may be formed in a box shape.

This plasma processing chamber 101 houses a mounting table 102 for placing a processing target (for example, a semiconductor wafer W) on an upper surface thereof. The mounting table 102 is made of, for example, anodized aluminum or the like and formed in a substantially columnar shape. The mounting table 102 has therein a heater H for heating the wafer W when necessary. The mounting table 102 further provides lift pins 103 for lifting the wafer W.

On the upper surface of the mounting table 102, an electrostatic chuck or a clamping mechanism (not shown) for keeping the wafer W supported on the upper surface is provided. Further, the mounting table 102 is connected to a matching box (not shown) and a high-frequency power source for bias (for example, for 13.56 MHz; not shown) via a feeder (not shown). Note that in a case of CVD processing or the like, that is, when the bias is not applied, this high-frequency power source for bias need not be provided.

A ceiling portion of the plasma processing chamber 101 has an opening, in which an insulating plate 104 (for example, about 20 mm in thickness) made of a ceramic dielectric such as, for example, quartz or Al₂O₃ and transmissive for a microwave is airtightly provided via a sealing member (not shown) such as an O-ring.

On an upper surface of the insulating plate 104, a slot plate 105 functioning as an antenna is provided. The slot plate 105 has a circular conductor plate 105a made of, for example, a disk-shaped thin copper plate, and a large number of slots 105b are formed in the circular conductor plate 105a, as shown in FIG. 2. Owing to these slots 105b, uniform electric field distribution is formed for a space in the processing space S.

The circular conductor plate 105a is constituted of a thin disk made of a conductive material, for example, silver- or gold-plated copper or aluminum. The circular conductor plate 105a may be in a square shape or a polygonal shape, not limited to the disk shape. In this embodiment, as the slot plate 105, used is a RLSA (Radial Line Slot Antenna) having a plurality of pairs of slots, the slots in each pair making a T shape or perpendicularly facing each other, and these pairs being arranged for example, concentrically, circularly, or spirally.

On an upper surface of the slot plate 105, a retardation plate 106 made of a highly dielectric material, for example, quartz, Al₂O₃, AlN, or the like is provided to cover the slot plate 105. The retardation plate 106, which is sometimes called a wavelength shortening plate, lowers the propagation speed of a microwave to shorten the wavelength thereof, thereby improving propagation efficiency of the microwave emitted from the slot plate 105.

The microwave is propagated from the waveguide 107 to the slot plate 105. The frequency of the microwave is not limited to 2.45 GHz but other frequency, for example, 8.35 GHz may be used. The microwave is generated by, for example, a microwave generator 108. The waveguide 107 has a rectangular waveguide 114 and a coaxial waveguide 115, and the coaxial waveguide 115 is composed of an outer conductor 115a and an inner conductor 115b. The microwave generated by the microwave generator 108 is uniformly propagated to the slot plate 105 via the rectangular waveguide 114 and the coaxial waveguide 115 and is further supplied uniformly from the slot plate 105 via the insulating plate 104.

A conductive shield cover is disposed on the retardation plate 106 to cover the slot plate 105, the retardation plate 106, and so on. A cooling plate 112 for cooling the slot plate 105, the retardation plate 106, the insulating plate 104, and so on is disposed on the shield cover, and refrigerant paths 113 for cooling these members are provided inside the cooling plate 112 and the sidewall 101a. The cooling plate 112 has an effect of preventing thermal deformation and breakage of the slot plate 105, the retardation plate 106, and the insulating plate 104 for stable plasma generation.

In the sidewall 101a of the aforesaid plasma processing chamber 101, gas supply nozzles 120 as gas supply ports for introducing rare gas such as Ar and Kr, and oxidizing gas such as O₂, nitriding gas such as N₂, or vapor-containing gas into the processing space S are provided at equal intervals. In the plasma substrate processing apparatus 100, for the purpose of uniform exhaust of the atmosphere in the processing space S, a gas baffle plate 121 is disposed to be substantially perpendicular to the sidewall 101a. The gas baffle plate 121 is supported by a supporting member 122. Further, on inner sides (sides facing the processing space S) of the sidewall 101a and the gas baffle plate 121, liners 123 made of, for example, quartz glass are disposed for preventing the occurrence of particles such as metal contamination generated from the walls due to the sputtering by ions.

Gas in the atmosphere in the plasma processing chamber 101 is uniformly exhausted by an exhaust device 125 via exhaust ports 124A, 124B.

As gas supply sources to the aforesaid gas supply nozzles 120 being the gas supply ports, an inert gas supply source 131, a process gas supply source 132, and a process gas supply source 133 are prepared, and these gas supply sources are connected to the gas supply nozzles 120 via inner opening/closing valves 131a, 132a, 133a, massflow controllers 131b, 132b, 133b, and outer opening/closing valves 131c, 132c, 133c, respectively. Flow rates of the gases supplied from the gas supply nozzles 120 are controlled by the massflow controllers 131b, 132b, 133b.

A controller 140 controls ON-OFF and output control of the aforesaid microwave generator 108, the flow rate adjustment by the massflow controllers 131b, 132b, 133b, adjustment of an exhaust amount of the exhaust device 125, the heater H of the mounting table 102, and so on so as to allow the plasma substrate processing apparatus 100 to perform the optimum processing.

This invention uses the plasma substrate processing apparatus 100 shown in FIG. 1 to apply plasma processing to be described below, thereby curing an insulating film in a short time while keeping a low dielectric constant.

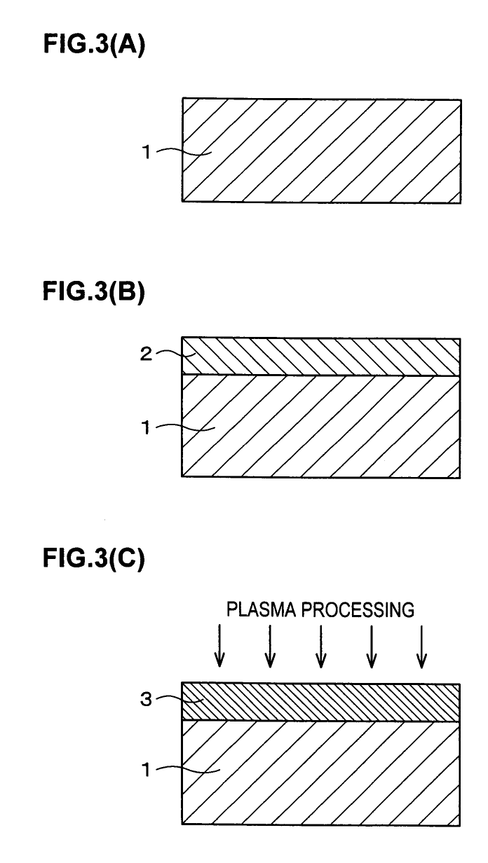

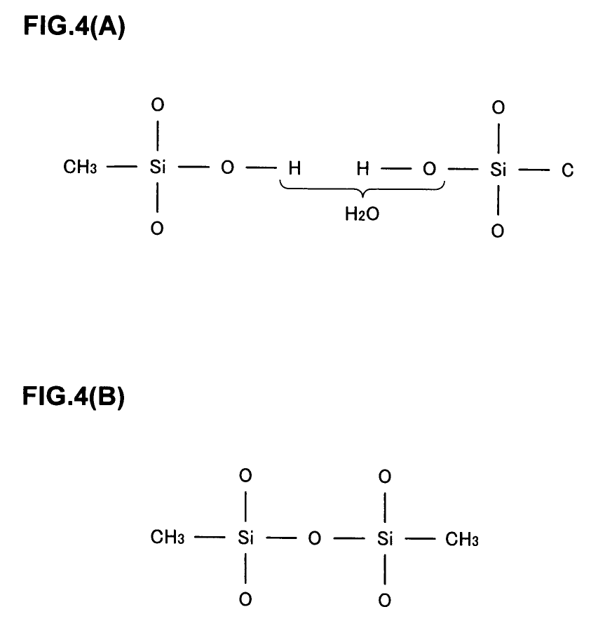

FIG. 3A to FIG. 3C are cross-sectional views of an insulating film, showing processes for forming the insulating film according to one embodiment of the present invention. FIG. 4A and FIG. 4B are views showing a molecular structure of the insulating film before being cured and a molecular structure of the insulating film plasma-processed by the plasma substrate processing apparatus 100.

First, a substrate 1 shown in FIG. 3A is prepared, the substrate 1 is coated with a low dielectric constant insulating film material by, for example, a generally-known SOD system, so that a coating film 2 is formed, as shown in FIG. 3B. Here, the applied insulative material is a low dielectric constant insulating film such as, for example, porous MSQ (Methyl Silsesqueoxane) whose dielectric constant is, for example, 2.4 or lower. As shown in FIG. 4A, the porous film MSQ has a structure such that one molecule is terminated with a hydroxyl bonded to Si of O—Si—O and the other molecule is terminated with a hydroxyl bonded to Si of O—Si—O, and it also includes a structure such that one molecule and the other molecule are dissociated.

Next, the substrate 1 on which the coating film 2 is formed is carried into the processing space of the plasma substrate processing apparatus 100 shown in FIG. 1 by a not-shown carrier. Then, non-mixed gas of argon (Ar), hydrogen (H₂), or helium (He) or mixed gas made of the combination of these is introduced into the processing space of the plasma substrate processing apparatus 100, and at the same time, the 2.45 GHz microwave is supplied to the coaxial waveguide 115, whereby plasma with a low electron temperature of 0.5 eV to 1.5 eV and an electron density of 10¹¹ to 10¹³ electrons/cm³ is generated in the processing space at a temperature of about 250° C. to about 400° C. By this high-density plasma, plasma processing is applied for curing the coating film 2, with a processing time of, for example, five minutes or less, more preferably, one minute to two minutes, so that the coating film 2 turns to a cured insulating film 3, as shown in FIG. 3C.

Note that the aforesaid low electron temperature was measured by a Langmuir probe in a space between the gas nozzles 120 of raw material gas and the silicon wafer W under the same condition in advance. Further, the electron temperature was also confirmed by Langmuir probe measurement.

By this plasma processing, one and the other molecules adjacent to each other are bonded together as shown in FIG. 4A and FIG. 4B. That is, hydrogen of the hydroxyl of one molecule shown in FIG. 4A is dissociated and the bond of the hydroxyl and Si of the other molecule is dissociated. Then, the dissociated hydrogen and hydroxyl are bonded into water, and this water is removed, so that intermolecular dehydration-condensation reaction takes place. By such intermolecular dehydration-condensation reaction, the Si—O—Si bond takes place as shown in FIG. 4B. By such Si—O—Si bond, the insulating film 3 cures.

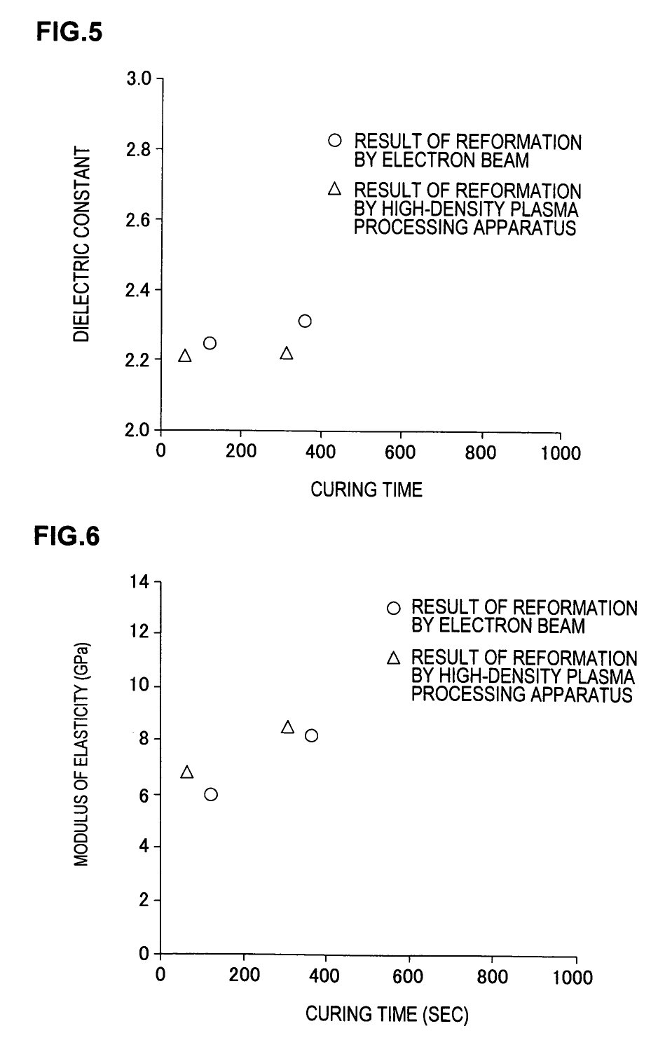

FIG. 5 is a view showing the correlation between curing time and dielectric constant in curing in the embodiment of the present invention and in conventional curing using an electron beam, and FIG. 6 is a view showing the correlation between curing time and modulus of elasticity in the curing in the embodiment of the present invention and in the conventional curing using the electron beam. In these drawings, circular marks represent the results of the conventional curing using the electron beam, and triangular marks represent the results of the plasma processing in the embodiment using the plasma substrate processing apparatus 100.

As shown in FIG. 5, in the curing by the electron beam, the dielectric constant is about 2.25 when the processing time is 120 seconds, and the dielectric constant becomes higher to about 2.3 when the processing time is set longer to 360 seconds. On the other hand, in this embodiment using the plasma substrate processing apparatus 100, the dielectric constant is about 2.2 when the plasma processing time is 60 seconds, and when the plasma processing time is set longer to 300 seconds, the dielectric constant only slightly exceeds the value of 2.2 and thus no significant change is seen in the dielectric constant. When the plasma processing time is between 60 seconds and 300 seconds, the dielectric constant also keeps the value of about 2.2. The processing time is preferably 1000 seconds or less, more preferably, 600 seconds or less.

That is, it is seen from FIG. 5 that the plasma processing using the plasma substrate processing apparatus 100 can achieve a lower dielectric constant than the curing by the electron beam. Further, it is seen that the use of the plasma substrate processing apparatus 100 can keep the dielectric constant substantially the same even when the plasma processing time becomes longer, while the use of the electron beam tends to increase the dielectric constant as the curing time becomes longer.

As is apparent from the correlation between modulus of elasticity and processing time shown in FIG. 6, in the case of using the electron beam, when the curing time is 120 seconds, modulus of elasticity is about 6 GPa, and when the curing time is 300 seconds, modulus of elasticity increases to about 8 GPa. On the other hand, in the case of using the plasma substrate processing apparatus 100, when the plasma processing time is 60 seconds, modulus of elasticity is about 6.5 GPa, and when the plasma processing time is 360 seconds, modulus of elasticity increases to about 8.2 GPa. When the plasma processing time falls within the range from 60 seconds to 300 seconds, the value of modulus of elasticity falls within the range from 6.5 GPa to 8.2 GPa. Thus, modulus of elasticity presents an increasing tendency as the processing time becomes longer both in the case of using the electron beam and in the case of using the plasma substrate processing apparatus 100. The processing time is preferably 60 seconds to 1000 seconds, more preferably, 60 seconds to 600 seconds.

Therefore, it is confirmed from the results shown in FIG. 5 and FIG. 6 that the curing using the electron beam can increase modulus of elasticity but also increases the dielectric constant when the processing time is set longer. On the other hand, the plasma processing using the plasma substrate processing apparatus 100 can not only increase modulus of elasticity and but also keep the dielectric constant at the same value when the processing time is set longer. In this case, the processing time is preferably 60 seconds to 1000 seconds, more preferably, 60 seconds to 600 seconds.

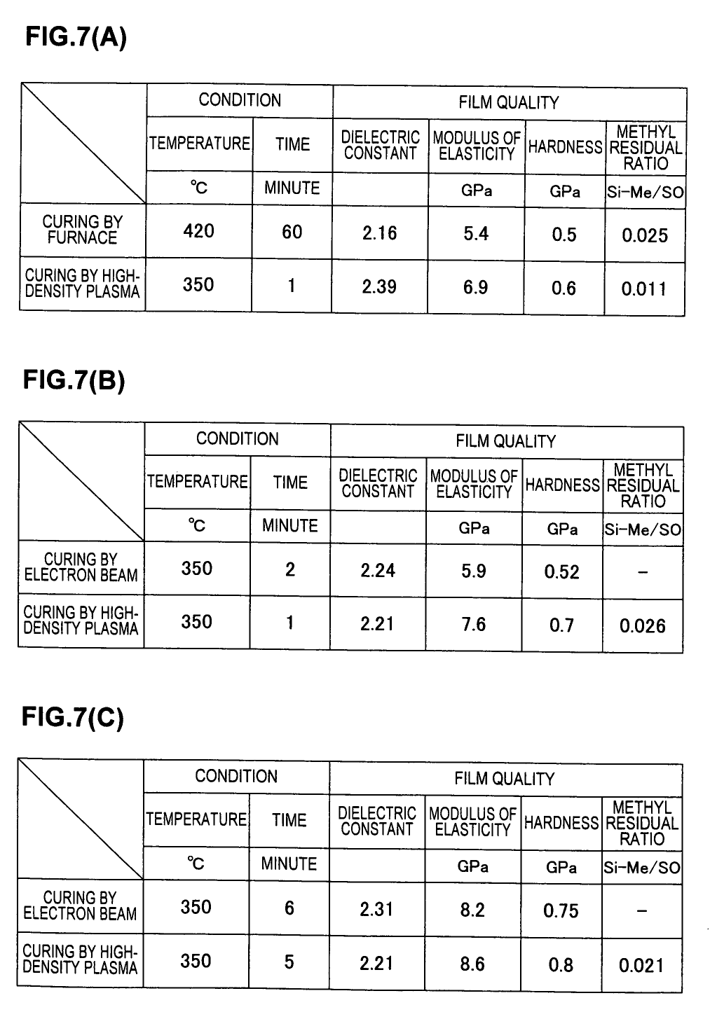

FIG. 7A to FIG. 7C are tables showing, for comparison, concrete experiment results of curing in another embodiment using the plasma substrate processing apparatus 100 and concrete experiment results of conventional curing using a furnace and conventional curing using the electron beam. Note that a MSQ1 film is used in FIG. 7A, while a MSQ2 film is used in FIG. 7B and FIG. 7C.

As shown in FIG. 7A, as a result of the curing by the furnace under the conditions that the temperature was 420° C. and the processing time was 60 minutes, the following film quality was obtained: dielectric constant 2.16, modulus of elasticity 5.4 GPa, hardness 0.5 GPa, and methyl residual ratio (Si—Me/SiO) 0.025. On the other hand, as a result of the plasma processing using the plasma substrate processing apparatus 100 under the condition that the temperature was 350° C. and the processing time was one minute, the following film quality was obtained: dielectric constant 2.39, modulus of elasticity 6.9 GPa, hardness 0.6 Gpa, and methyl residual ratio 0.011.

It is apparent from these results that the plasma processing in the embodiment using the plasma substrate processing apparatus 100 can extremely shorten the time taken for the curing, and as for the film quality, can increase modulus of elasticity and hardness, though slightly increasing a dielectric constant, compared with the conventional curing by the furnace.

Further, as shown in FIG. 7B, as a result of the curing by the electron beam under the condition that the temperature was 350° C. and the processing time was two minutes, the following film quality was obtained: dielectric constant 2.24, modulus of elasticity 5.9 GPa, and hardness 0.52 GPa. At this time, the residual ratio of a methyl group could not be confirmed. On the other hand, as a result of the plasma processing by the plasma substrate processing apparatus 100 under the condition that the temperature was 350° C. and the processing time was one minute, the following film quality was obtained: dielectric constant 2.21, modulus of elasticity 7.6 GPa, hardness 0.7 GPa, and methyl residual ratio 0.026. It is seen from these results that the dielectric constant can be made lower while the methyl group is allowed to exist.

Moreover, as shown in FIG. 7C, as a result of the curing by the electron beam under the condition that the temperature was 350° C. and the processing time was six minutes, the following film quality was obtained; dielectric constant 2.31, modulus of elasticity 8.2 GPa, and hardness 0.75 GPa. At this time, the residual ratio of the methyl group could not be confirmed. On the other hand, as a result of the plasma processing by the plasma substrate processing apparatus 100 under the condition that the temperature was 350° C. and the processing time was five minutes, the following film quality was obtained: dielectric constant 2.21, modulus of elasticity 8.6 GPa, hardness 0.8 GPa, and methyl residual ratio 0.021.

It is seen from these results that the value of the dielectric constant in the conventional curing by the electron beam is substantially the same as the value of the dielectric constant in the plasma processing by the plasma substrate processing apparatus 100, but the processing by the plasma substrate processing apparatus 100 can more increase modulus of elasticity and hardness while allowing the methyl group to remain.

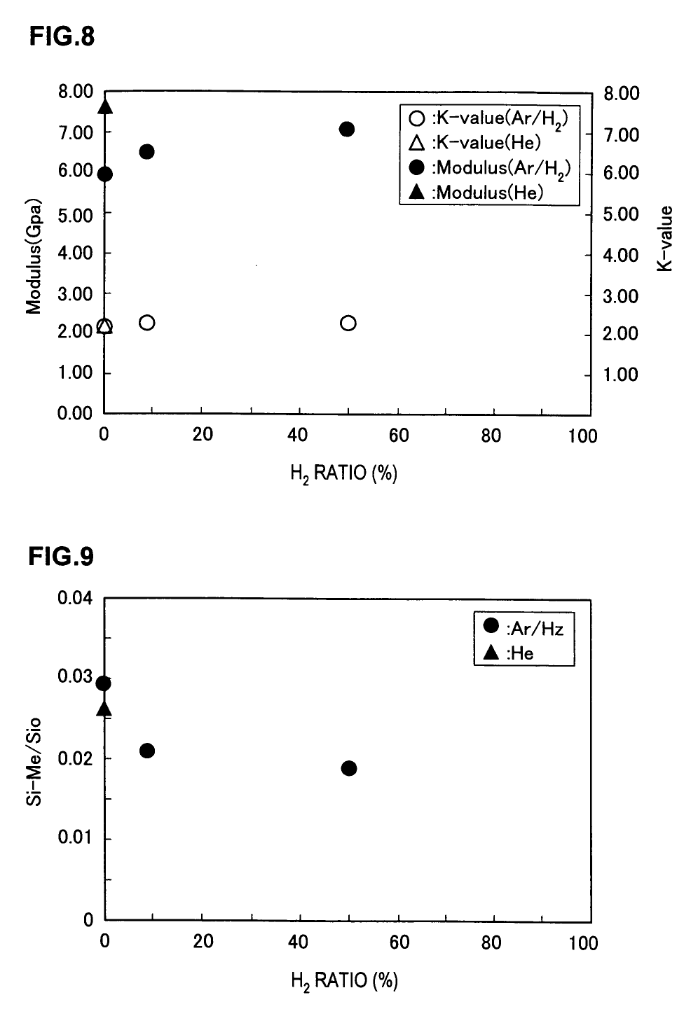

Next, FIG. 8 shows changes in modulus of elasticity (GPa) and dielectric constant to. a hydrogen gas ratio when the MSQ2 film is cured by the plasma processing by the plasma substrate processing apparatus 100 while a flow rate ratio of argon gas/hydrogen gas in the process gas is varied. At this time, the temperature for processing the substrate 1 is 350°, the process pressure is 0.5 Torr, and the processing time is 60 seconds. It is seen from the results that modulus of elasticity increases from 6.0 to 7.1 GPa, while the dielectric constant keeps a low value of 2.2 even when the hydrogen gas ratio is increased up to 50 percent. Further, as for the methyl residual ratio when the processing is applied under the same conditions, the methyl residual ratio gets lower as the hydrogen gas ratio increases, and when the hydrogen gas ratio is 50%, the methyl residual ratio is 0.019, as shown in FIG. 9.

As is seen from the above, when the curing is applied by the plasma processing by the plasma substrate processing apparatus 100, increasing the hydrogen gas mixture ratio makes it possible to increase modulus of elasticity as film quality while keeping the low dielectric constant. More preferably, the hydrogen gas mixture ratio is 50% or lower. This is because the increase in the H₂ ratio lowers a ratio of high-energy Ar+, so that the decomposition of Si—Me is inhibited, resulting in increased hardness.

For reference, FIG. 8 and FIG. 9 also show results obtained when non-mixed gas of helium is used as the process gas used in the plasma processing. It has been found out from these results that it is possible to obtain a still higher value for modulus of elasticity while the dielectric constant keeps the same low value as in the case of using argon gas/hydrogen gas.

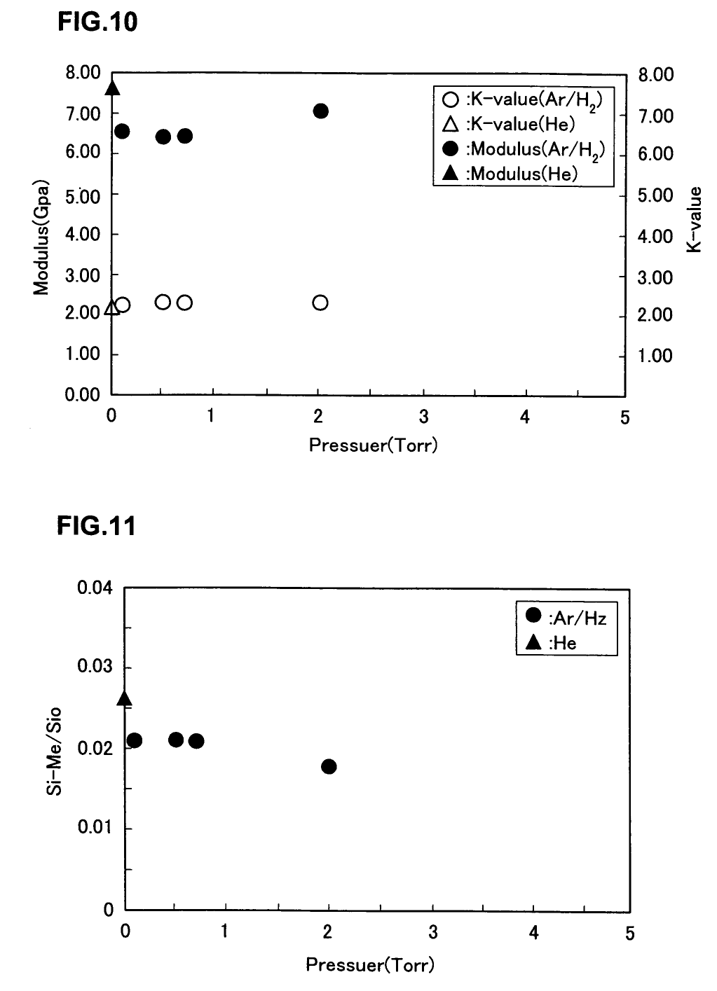

Next, pressure dependency was studied. Specifically, as a process gas condition, a flow rate ratio of hydrogen gas in argon gas/hydrogen gas was fixed to 10% (argon gas/hydrogen gas=1000/100 SCCM), the temperature of the substrate was set to 350°, and the processing time was set to 60 seconds. Changes in modulus of elasticity (Gpa) and dielectric constant under these conditions with the process pressure being varied from 0.1 Torr to 2.0 Torr are shown in FIG. 10, and a change in methyl residual ratio in the same case is shown in FIG. 11.

From these results, it has been found out that even the processing under the increased process pressure causes no change in dielectric constant, but causes an increase in modulus of elasticity from 6.5 to 7.1 GPa. Further, as for the methyl residual ratio, it has been found out that the increase in the process pressure causes a decrease in the methyl residual ratio, but even under the process pressure of 2.0 Torr, the methyl residual ratio keeps 0.018. Therefore, the processing under the increased process pressure makes it possible to increase modulus of elasticity as film quality while keeping the low dielectric constant. The process pressure is preferably 2.0 Torr or lower. Such processing under the high pressure contributes to hardness increase of the film since the plasma mainly composed of radicals inhibits the decomposition of Si—Me in the film.

Incidentally, FIG. 10 and FIG. 11 also show results when non-mixed gas of helium is used as the process gas in the plasma processing. It has been found out from these results that the dielectric constant is the same as in the case of hydrogen gas, but a still higher value is obtained for modulus of elasticity.

Further, in this embodiment, since the use of the plasma substrate processing apparatus 100 using the microwave can produce the atmosphere at a low electron temperature, damage to the insulating film can be alleviated. Specifically, high electron temperature increases sheath bias voltage, which increases energy when electrons in the plasma are directed to the insulating film, so that the insulating film is damaged when the electrons collide with the insulating film. On the other hand, when the electron temperature is low, the energy when the electrons are directed to the insulating film gets small, which can alleviate the damage to the insulating film when the electrons collides with the insulating film and can lower the dielectric constant without lowering the methyl group residual ratio.

Further, setting the curing time to five minutes or less, more preferably, one minute to two minutes makes it possible to process 20 to 30 wafers per hour, even if the transfer time of the wafers is taken into consideration, which enables improved throughput in semiconductor processing processes.

In the above-described example, the plasma is generated by the microwave, but a plasma generating means (plasma source) in the present invention is not limited to any specific one. That is, besides the microwave, plasma sources such as, for example, ICP (inductively coupled plasma), ECR, a surface reflected wave, magnetron, and the like are also usable.

Hitherto, the embodiment of the present invention has been described with reference to the drawings. However, the present invention is not limited to the shown embodiment. Various kinds of changes can be made to the shown embodiment within the same range as or an equivalent range to that of the present invention.

The present invention is useful for forming a low dielectric constant insulating film in manufacturing processes of various kinds of semiconductor devices.

What is claimed is:

1. A forming method of a low dielectric constant insulating film of a semiconductor device, for forming a low dielectric constant insulating film in a semiconductor device, the method comprising the step of
placing in a vacuum vessel a substrate on which a coating film is formed and applying, to the coating film, high-density plasma processing at a low electron temperature based on microwave excitation, thereby curing the coating film while keeping a low dielectric constant.

2. The forming method of the low dielectric constant insulating film of the semiconductor device according to claim 1,
wherein said curing step includes curing the coating film in a processing time of five minutes or less.

3. The forming method of the low dielectric constant insulating film of the semiconductor device according to claim 1,
wherein said curing step includes generating plasma with a low electron temperature of 0.5 eV to 1.5 eV.

4. The forming method of the low dielectric constant insulating film of the semiconductor device according to claim 3,
wherein the plasma has an electron density of 10¹¹ to 10¹³ electrons/cm³.

5. The forming method of the low dielectric constant insulating film of the semiconductor device according to claim 1,
wherein said curing step includes causing an intermolecular dehydration-condensation reaction by hydroxyls in a molecule and another molecule included in the coating film.

6. The forming method of the low dielectric constant insulating film of the semiconductor device according to claim 3,
wherein gas introduced into the vessel when the plasma is generated is mixed gas of argon gas and hydrogen gas.

7. The forming method of the low dielectric constant insulating film of the semiconductor device according to claim 6,
wherein a mixture ratio of the hydrogen gas is 50% or lower.

8. The forming method of the low dielectric constant insulating film of the semiconductor device according to claim 3,
wherein gas introduced into the vessel when the plasma is generated is helium gas.

9. The forming method of the low dielectric constant insulating film of the semiconductor device according to claim 3,
wherein pressure in the vessel at the time of the plasma processing is 2.0 Torr or lower.

10. A forming method of a low dielectric constant insulating film of a semiconductor device, for forming a low dielectric constant insulating film in a semiconductor device, the method comprising the step of
placing in a vacuum vessel a substrate on which a coating film is formed and applying plasma processing to the coating film by plasma with a low electron temperature of 0.5 eV to 1.5 eV generated via an antenna, thereby curing the coating film while keeping a low dielectric constant.

11. The forming method of the low dielectric constant insulating film of the semiconductor device according to claim 10, wherein the plasma has an electron density of 10¹¹ to 13¹³ electrons/cm³.

12. The forming method of the low dielectric constant insulating film of the semiconductor device according to claim 10,
wherein a processing time of said curing is 1000 seconds or less.

13. A semiconductor device having an insulating film, comprising:
a substrate; and
a low dielectric constant insulating film applied on said substrate and cured by high-density plasma processing at a low electron temperature of 0.5 eV to 1.5 eV.

14. The semiconductor device according to claim 13,
wherein a molecular structure of the insulating film cured by the high-density plasma processing has a Si—O—Si bond.

15. A low dielectric constant insulating film forming apparatus that forms
a low dielectric constant insulating film, the apparatus comprising:
a curing means for curing the insulating film while keeping a low dielectric constant, by placing in a vacuum vessel a substrate on which a coating film is formed, generating high-density plasma with a low electron temperature of 0.5 eV to 1.5 eV via an antenna, and plasma-processing the coating film by the high-density plasma.

16. The low dielectric constant insulating film forming apparatus according to claim 15,
wherein the high-density plasma has an electron density of 10¹¹ to 13¹³ electrons/cm³.
